(19) United States
(12) Patent Application Publication
(10) Pub. No.: US 2026/0275563 A1
(43) Pub. Date: Sep. 17, 2026

(54) ELECTROPLATING APPARATUS

(71) Applicant: ACM RESEARCH (SHANGHAI), INC., Shanghai (CN)

(72) Inventors: Chen Wang, Shanghai (CN); Yinuo Jin, Shanghai (CN); Jian Wang, Shanghai (CN); Hui Wang, Shanghai (CN); Hongchao Yang, Shanghai (CN)

(73) Assignee: ACM RESEARCH (SHANGHAI), INC., Shanghai (CN)

(21) Appl. No.: 19/156,746

(22) PCT Filed: Jan. 30, 2024
(86) PCT No.: PCT/CN2024/074776

§ 371 Date: Aug. 14, 2025

(30) Foreign Application Priority Data
Feb. 14, 2023 (CN) 202310115061.1

(51) Int. Cl. C25D 17/00; C25D 7/12; C25D 17/06; C25D 17/10; C25D 21/10; H10P 14/47

(52) U.S. Cl. CPC C25D 17/001; C25D 7/12; C25D 17/06; C25D 17/10; C25D 21/10; H10P 14/47

(57) ABSTRACT

The present invention provides an electroplating apparatus. A solid anode, a meshed anode or a perforated anode is arranged in the anode region to serve as an inert anode. And the constant distance is maintained between the inert anode and a substrate, so as to form a stable electric field on the surface of the substrate, thereby improving the uniformity of electroplating. An active anode is arranged below the inert anode in the anode region, so as to continuously replenish metal ions during the electroplating process, so that the metal ions can be more sufficiently conveyed to the substrate, thereby playing a role in improving the uniformity of electroplating. Components such as a rectifying plate, a fluid dispersion pipe or a stirring member are arranged in the anode region, so as to uniformly disperse the anode liquid, thereby further improving the uniformity of electroplating.

### FIELD OF THE INVENTION

The present invention relates to the field of semiconductor manufacturing equipment, and more particularly to an electroplating apparatus.

### BACKGROUND

Semiconductor electroplating refers to the electroplating of metal ions in electroplating liquid onto the surface of a substrate (such as a wafer) to form metal interconnect lines during the chip manufacturing process.

The metal block serves as an anode to replenish metal ions consumed in electroplating liquid. During the electroplating process, the surface of the metal block is continuously consumed, so that the distance between the metal block and the substrate as a cathode continues to increase. In addition, the flat surface of the metal block also becomes uneven with the process, causing the distance between different positions on the surface of the metal block and the substrate to change, which affects the deposition rate of the metal on the surface of the substrate, and thus causes the plating thickness distribution on the surface of the substrate to be uneven.

Therefore, it is necessary to improve the electroplating apparatus, in order to improve the uniformity of substrate electroplating.

### SUMMARY

An object of the present invention is to provide an electroplating apparatus, for solving the problem of uneven electroplating of the substrate in the prior art.

In order to achieve the above and other related objects, the present invention provides an electroplating apparatus, comprising:
a clamp, for clamping a substrate;
an anode chamber, including at least one independent anode region, each anode region being configured with:
a solid anode, being an inert anode, and disposed below the substrate and disposed opposite to the substrate in parallel;
an active anode, disposed below the solid anode, for replenishing metal ions;
at least one anode liquid inlet, for supplying anode liquid to the anode region;
at least one anode liquid outlet, for discharging anode liquid from the anode region;
at least one internal fluid channel, disposed in the wall surface of the anode region, for guiding anode liquid to flow from the anode liquid inlet to the anode liquid outlet.

In order to achieve the above and other related objects, the present invention also provides an electroplating apparatus, comprising:
a clamp, for clamping a substrate;
an anode chamber, including at least one independent anode region, each anode region being configured with:
a meshed anode, being an inert anode, and disposed below the substrate and disposed opposite to the substrate in parallel;
an active anode, disposed below the meshed anode, for replenishing metal ions;
at least one anode liquid inlet, for supplying anode liquid to the anode region;
at least one anode liquid outlet, for discharging anode liquid from the anode region.

In order to achieve the above and other related objects, the present invention also provides an electroplating apparatus, comprising:
a clamp, for clamping a substrate;
an anode chamber, including at least one independent anode region, each anode region being configured with:
a perforated anode, being an inert anode, and disposed below the substrate and disposed opposite to the substrate in parallel;
an active anode, disposed below the perforated anode, for replenishing metal ions;
at least one anode liquid inlet, for supplying anode liquid to the anode region;
at least one anode liquid outlet, for discharging anode liquid from the anode region;
wherein, a perforation is formed on the perforated anode, the perforated anode has a first surface parallel to the substrate, the first surface of the perforated anode of the respective anode regions collectively constitutes an electric field generating surface, the size of the electric field generating surface is equal to the size of the effective electroplating surface of the substrate.

In order to achieve the above and other related objects, the present invention also provides an electroplating apparatus, comprising:
a clamp, for clamping a substrate;
an anode chamber, including at least one independent anode region, each anode region being configured with:
a perforated anode, having a perforation formed thereon, and being an inert anode, disposed below the substrate and disposed opposite to the substrate in parallel;
an active anode, disposed below the perforated anode, for replenishing metal ions;
at least one anode liquid inlet, for supplying anode liquid to the anode region;
at least one anode liquid outlet, for discharging anode liquid from the anode region;
wherein, a rectifying plate is disposed in at least one anode region, and the rectifying plate is disposed between the anode liquid inlet and the active anode in the anode region where the rectifying plate is located.

In order to achieve the above and other related objects, the present invention also provides an electroplating apparatus, comprising:
a clamp, for clamping a substrate;
an anode chamber, including at least one independent anode region, each anode region being configured with:
a perforated anode, having a perforation formed thereon, and being an inert anode, disposed below the substrate and disposed opposite to the substrate in parallel;
an active anode, disposed below the perforated anode, for replenishing metal ions;
at least one anode liquid inlet, for supplying anode liquid to the anode region;
at least one anode liquid outlet, for discharging anode liquid from the anode region;
wherein, a stirring member is disposed in at least one anode region, the stirring member including:
a magnetic stirring bar, located between the active anode and the anode liquid inlet in the anode region where the magnetic stirring bar is located;
a magnetic generator, located outside the anode region where the magnetic generator is located, and being used to drive the magnetic stirring bar to rotate.

In order to achieve the above and other related objects, the present invention also provides an electroplating apparatus, comprising:
a clamp, for clamping a substrate;
an anode chamber, including at least one independent anode region, each anode region being configured with:
a perforated anode, having a perforation formed thereon, and being an inert anode, disposed below the substrate and disposed opposite to the substrate in parallel;
an active anode, disposed below the perforated anode, for replenishing metal ions;
at least one anode liquid inlet, for supplying anode liquid to the anode region;
at least one anode liquid outlet, for discharging anode liquid from the anode region;
wherein, a fluid dispersion pipe and an anode liquid inlet pipe are disposed in at least one anode region, the fluid dispersion pipe is located above the perforated anode in the anode region where the fluid dispersion pipe is located, and is communicated with the anode liquid inlet in the anode region where the fluid dispersion pipe is located through the anode liquid inlet pipe, so as to uniformly disperse the anode liquid.

As described above, the present invention provides an electroplating apparatus, having the following beneficial effects:
1) The solid anode, the meshed anode or the perforated anode is disposed in the anode region to serve as the inert anode, and the constant distance is maintained between the inert anode and the substrate, so that the stable electric field is formed on the surface of the substrate, thereby improving the uniformity of electroplating;
2) The active anode is disposed below the inert anode in the anode region, so as to continuously replenish metal ions during the electroplating process, so that the metal ions can be more sufficiently conveyed to the substrate, thereby playing a role in improving the uniformity of electroplating;
3) Components such as the rectifying plate, the fluid dispersion pipe or the stirring member are disposed in the anode area, so that the anode liquid is uniformly dispersed, further improving the uniformity of electroplating.

### BRIEF DESCRIPTION OF THE DRAWINGS

The features and performances of the present invention are further described by the following embodiments and the accompanying drawings.

FIG. 1 is a schematic view of an electroplating apparatus according to the first embodiment of the present invention;

FIG. 2 is a schematic view of another electroplating apparatus according to the first embodiment of the present invention;

FIG. 3 is a schematic top view of an anode chamber according to the first embodiment of the present invention;

FIG. 4 is a schematic view of an electroplating apparatus according to the second embodiment of the present invention;

FIG. 5 is a schematic view of an electroplating apparatus according to the third embodiment of the present invention;

FIG. 6 is a schematic view of another electroplating apparatus according to the third embodiment of the present invention;

FIG. 7 is a schematic view of an electroplating apparatus according to the fourth embodiment of the present invention;

FIG. 8 is a schematic top view of an anode chamber according to the fourth embodiment of the present invention;

FIG. 9 is a schematic view of an electroplating apparatus according to the fifth embodiment of the present invention;

FIG. 10 is a schematic view of an electroplating apparatus according to the sixth embodiment of the present invention;

FIG. 11 is a schematic view of another electroplating apparatus according to the sixth embodiment of the present invention;

FIG. 12a is a schematic top view of a fluid dispersion pipe according to the sixth embodiment of the present invention;

FIG. 12b is a schematic top view of a modification of a fluid dispersion pipe according to the sixth embodiment of the present invention;

FIG. 13 is a schematic view of an electroplating apparatus according to the seventh embodiment of the present invention;

FIG. 14 is a schematic view of another electroplating apparatus according to the seventh embodiment of the present invention;

FIG. 15 is a schematic view of an electroplating apparatus according to the eighth embodiment of the present invention;

FIG. 16 is a schematic view of another electroplating apparatus according to the eighth embodiment of the present invention;

FIG. 17 is a schematic top view of an anode chamber according to the eighth embodiment of the present invention;

FIG. 18 is a schematic view of an electroplating apparatus according to the ninth embodiment of the present invention;

FIG. 19 is a schematic view of an electroplating apparatus according to the tenth embodiment of the present invention;

FIG. 20 is a schematic view of an electroplating apparatus according to the eleventh embodiment of the present invention; and

FIG. 21 is a schematic view of another electroplating apparatus according to the eleventh embodiment of the present invention.

### PREFERRED EMBODIMENTS OF THE INVENTION

Hereinafter, embodiments of the present invention will be described with specific embodiments, and other advantages and effects of the present invention will be readily apparent to those of ordinary skill in the art from the disclosure of this specification. The present invention can also be embodied or applied by other different and specific embodiments, and various details in this specification can also be modified or changed based on different viewpoints and applications without departing from the spirit of the present invention.

It should be explained that the drawings provided in the present embodiments illustrate the basic concept of the present invention only in a schematic manner, and although only components related to the present invention are shown in the drawings and are not drawn according to the numbers, shapes and sizes of the components in actual implementation, the form, number and proportion of each component in actual implementation may be arbitrarily changed, and the layout of the components may be more complicated. In addition, portions denoted by the same reference numerals in a plurality of drawings denote the same or equivalent portions or components.

### Embodiment 1

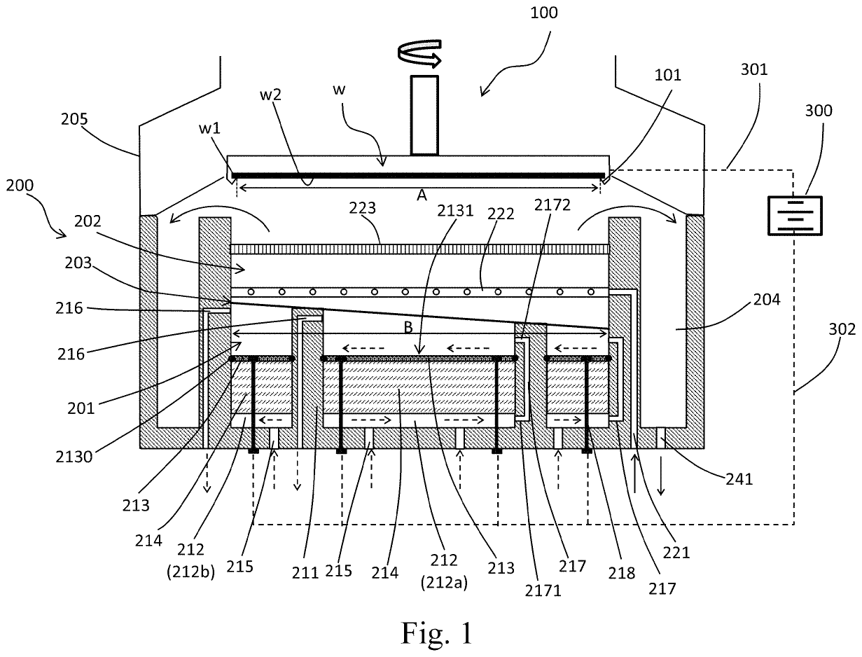

As shown in FIG. 1, the present embodiment proposes an electroplating apparatus, comprising a clamp 100 and an electroplating chamber 200. The clamp 100 is used to clamp the substrate w. The clamp 100 can drive the substrate w to perform actions such as rotation, inclination and lifting/lowering. The clamp 100 is provided with a sealing member 101 partitioning the surface of the substrate w into a first region w1 and a second region w2. The first region w1 is wrapped by the sealing member 101 and is not in contact with the electroplating liquid; The second region w2 is exposed outside the clamp 100 and is in contact with the electroplating liquid. Wherein, the second region w2 is an effective electroplating surface of the substrate w, and metal ions are deposited on the second region w2 when electroplating.

The electroplating chamber 200 comprises an anode chamber 201, a cathode chamber 202 disposed above the anode chamber 201, an ionic membrane 203 separating the anode chamber 201 and the cathode chamber 202, a peripheral chamber 204 surrounding the outside of the anode chamber 201 and the cathode chamber 202, and a protective cover 205 disposed above the peripheral chamber 204. The anode chamber 201 is used for storing anode liquid, and the cathode chamber 202 is used for storing cathode liquid, the anode liquid and cathode liquid are collectively referred to as the electroplating liquid.

The cathode chamber 202 is provided with a cathode liquid inlet 221, a cathode liquid supply pipe 222 and a diffusion plate 223. As shown by the solid arrows in FIG. 1, the cathode liquid enters the cathode liquid supply pipe 222 from the cathode liquid inlet 221, then is supplied to the cathode chamber 202 from the cathode liquid supply pipe 222, then overflows upward to the peripheral chamber 204 through the diffusion plate 223, and finally is discharged from the cathode liquid outlet 241 set at the bottom of the peripheral chamber 204. The diffusion plate 223 is disposed above the cathode liquid supply pipe 222, so as to uniformly disperse the cathode liquid in the cathode chamber 202. It can be understood that the cathode liquid outlet 241 may be communicated with the cathode liquid inlet 221 through an external circulation pipeline (not shown), so as to circulate and flow the cathode liquid.

The anode chamber 201 comprises at least one independent anode region 212, and each anode region 212 is provided with a solid anode 213, an active anode 214 and an anode liquid supply member. In this embodiment, without limiting the present invention, a partition wall 211 is provided in the anode chamber 201, and the partition wall 211 separates the anode chamber 201 into two independent anode regions 212, and the two anode regions 212 are arranged in a concentric circle. In each anode region 212, the active anode 214 is disposed below the solid anode 213, and the active anode 214 is continuously consumed during the electroplating process for the replenishment of metal ions. The active anode 214 may be a metal block or metal granules, such as a copper block or copper granules.

The solid anode 213 is the inert anode and is made of the inert material, such as titanium metal (Ti). The surface of the solid anode 213 may also has gold (Au) or platinum (Pt) coating. During the electroplating process, the solid anode 213 can provide the stable potential, and the solid anode 213 is not consumed, the distance between the solid anode 213 and the substrate w can be maintained constant. Hence, the electric field generated by the solid anode 213 on the substrate w does not change with the lapse of electroplating time, and the uniformity of electroplating can be improved to some extent.

The solid anode 213 is in the shape of flat plate, and the anode regions 212 where the solid anode 213 is located are separated into an upper space and a lower space independent of each other. The anode liquid in the lower space flows upward into the upper space only through the internal fluid channels 217 described later, so as to reduce the influence of the flow of anode liquid on the electric field generated by the solid anode 213. In order to prevent the anode liquid in the lower space from flowing upward into the upper space through the side wall of the solid anode 213, the solid anode 213 is in sealing contact with the wall surfaces (such as the side wall surfaces) of the anode regions 212 where the solid anode 213 is located. For example, O-shaped sealing rings 2130 are provided between the side wall of the solid anode 213 and the side walls of the anode regions 212 where the solid anode 213 is located.

The solid anode 213 is located below the substrate w, and is disposed opposite to the substrate w in parallel. The solid anode 213 has the first surface 2131, and the first surface 2131 is the flat and closed plane arranged opposite to the effective electroplating surface of the substrate w. The first surface 2131 of the solid anode 213 of the respective anode regions 212 collectively constitute the electric field generating surface, and the size B of the electric field generating surface is equal to the size A of the effective electroplating surface (i.e., the second region w2) of the substrate w, so that the solid anode 213 forms the uniform electric field on the effective electroplating surface of the substrate w. It is to be understood that “equal” herein allows for a certain degree of error, i.e., includes approximately equal cases.

The electroplating apparatus is further provided with an electroplating power supply 300, for controlling the current (or voltage) in the substrate w. The negative electrode of the electroplating power supply 300 is connected to the clamp 100 through a wire 301, so as to supply power to the substrate w in the clamp 100. Each anode region 212 is further configured with conductive posts 218. The conductive posts 218 may be selected from titanium metal (Ti). The electroplating power supply 300 is connected to the conductive posts 218 by a lead 302, the conductive posts 218 are electrically connected to the solid anode 213 and the active anode 214, and the electroplating power supply 300 supplies power to the solid anode 213 and the active anode 214 through the conductive posts 218.

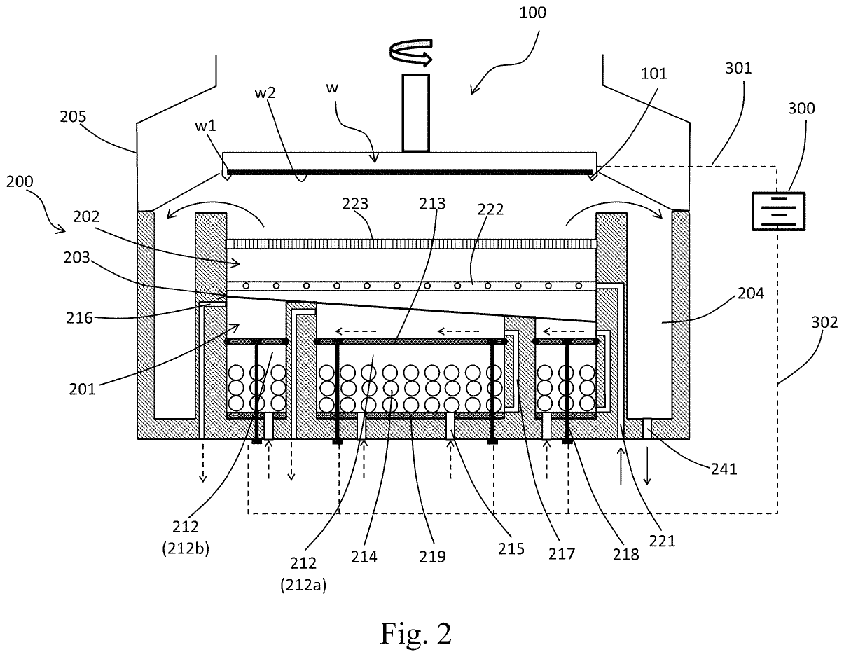

In one embodiment, as shown in FIG. 1, the active anode 214 may be the metal block and is directly inverted below the solid anode 213. At this time, the solid anode 213 may be electrically connected to the electroplating power supply 300 through the conductive posts 218, and the solid anode 213 may also serve as a conductive plate, so as to supply power to the active anode 214. In the other embodiment, as shown in FIG. 2, the active anode 214 may be metal granules laid flat on the conductive plate 219 disposed below the solid anode 213. At this time, the solid anode 213 is electrically connected to the electroplating power supply 300 through the conductive posts 218, and the conductive plate 219 is electrically connected to the electroplating power supply 300 through the conductive posts 218, so as to supply power to the active anode 214.

In the above description, the solid anode 213 and the active anode 214 share the conductive posts 218 as an embodiment to explain, and it can be understood that in other embodiments, the solid anode 213 and the active anode 214 may each independently configure the conductive posts 218 electrically connected to the electroplating power supply 300, so that the electroplating power supply 300 can independently control the solid anode 213 and the active anode 214, respectively.

Besides, it should be noted that the electroplating power supply 300 may independently control each anode or may synchronously control a part of the anode in each anode. For example, the electroplating power supply 300 may independently control the current (or voltage) in the solid anode 213 and the active anode 214 of the same anode regions 212, or may synchronously control the current (or voltage) in the solid anode 213 and the active anode 214 of the same anode regions 212.

Each anode region 212 is provided with the independent anode liquid supply member, for supplying anode liquid to the anode regions 212. As shown in FIG. 1, the anode liquid supply member of each anode region 212 comprises at least one anode liquid inlet 215 disposed below the active anode 214, for supplying anode liquid to the anode regions 212; At least one anode liquid outlet 216 is disposed above the solid anode 213, for discharging anode liquid from the anode regions 212; And at least one internal fluid channel 217 is disposed in the side wall of the anode regions 212, for guiding the anode liquid to flow from the anode liquid inlets 215 to the anode liquid outlets 216.

In this embodiment, two anode liquid inlets 215 are disposed at the bottom of the anode region 212a of the inner ring, and two anode liquid inlets 215 are disposed at the bottom of the anode region 212b of the outer ring. The anode liquid in each anode region 212 can flush the active anode 214 from bottom to top, which is beneficial to promote the diffusion of metal ions generated by the active anode 214 on the one hand, and beneficial to remove anode slimes on the surface of the active anode 214 on the other hand. In one embodiment, as shown in FIG. 1, the active anode 214 is the metal block, and the anode liquid enters each anode region 212 from the anode liquid inlets 215 and flushes the lower surface of the active anode 214, so that metal ions generated by the active anode 214 can be uniformly dispersed in the anode liquid, and more fully conveyed to the cathode region through the internal fluid channels 217 configured in each anode region 212. In the other embodiment, as shown in FIG. 2, the active anode 214 is metal granules, and the anode liquid enters each anode region 212 from the anode liquid inlets 215 and continuously flows in the gaps between metal granules, so that metal ions generated by the active anode 214 are continuously conveyed to the cathode region through the internal fluid channels 217 arranged in each anode region 212.

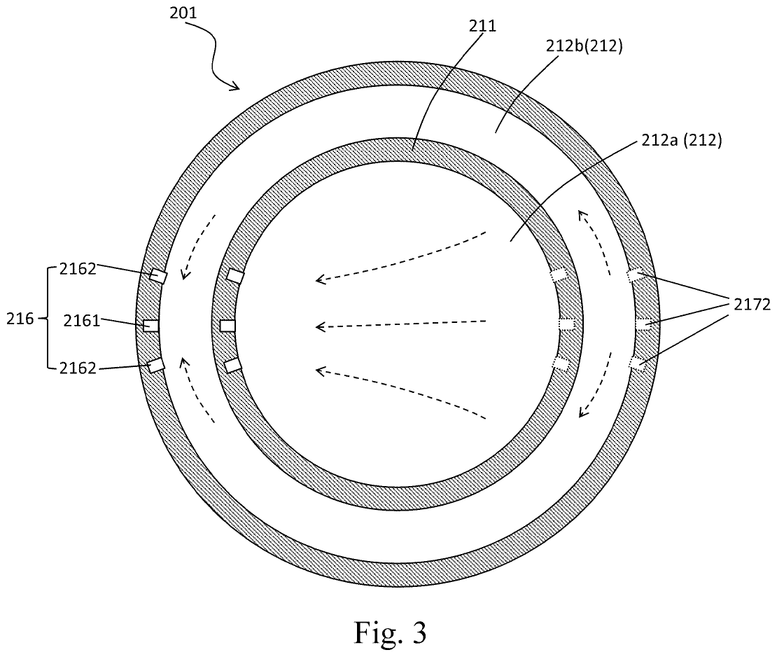

One of the at least one anode liquid outlets 216 arranged for each anode region 212 is located at the highest point of the anode region 212 where the anode liquid outlet 216 is located. In a preferred embodiment, referring to FIG. 3, each anode region 212 comprises a first anode liquid outlet 2161 and at least a pair of second anode liquid outlets 2162, wherein the first anode liquid outlet 2161 is located at the highest point (vertical direction in FIG. 2) of the anode regions 212 where the first anode liquid outlet 2161 is located, and the second anode liquid outlets 2162 are arranged in pairs on both sides of the first anode liquid outlet 2161 of the anode regions 212 where the second anode liquid outlets 2162 are located. In FIG. 3, each of the anode regions 212a and 212b is provided with a first anode liquid outlet 2161 and a pair of second anode liquid outlets 2162.

In the present embodiment, as shown in FIG. 1, in each anode region 212, the inlet ends 2171 of the internal fluid channels 217 communicate with the anode liquid inlets 215 through the space below the active anode 214; The outlet ends 2172 of the internal fluid channels 217 communicate with the anode liquid outlets 216 through the space above the solid anode 213. It will be appreciated that in the embodiment shown in FIG. 2, in each anode region 212, the inlet ends 2171 of the internal fluid channels 217 communicate with the anode liquid inlets 215 through the gaps between metal granules.

Besides, in the present embodiment, three internal fluid channels 217 are configured within the side walls of each anode region 212. Referring in conjunction with FIGS. 1 and 3, in each anode region 212, the outlet ends 2172 of the internal fluid channels 217 are disposed opposite to the anode liquid outlets 216. Specifically, the outlet ends 2172 of the internal fluid channels 217 and the anode liquid outlets 216 are respectively disposed on the wall surfaces opposite to the anode regions 212, so that the anode liquid smoothly flows from one side of the solid anode 213 to the other side, as shown by the dashed arrows in FIG. 3.

It should be explained that FIG. 3 is merely an embodiment, and is not used to limit the number of internal fluid channels 217 and anode liquid outlets 216 arranged in each anode region 212 and the relative positional relationship between the two. The number and positional relationship of internal fluid channels 217 and anode liquid outlets 216 in each anode region 212 can be reasonably optimized according to parameters such as fluid flux and flow field distribution in the anode regions 212.

### Embodiment 2

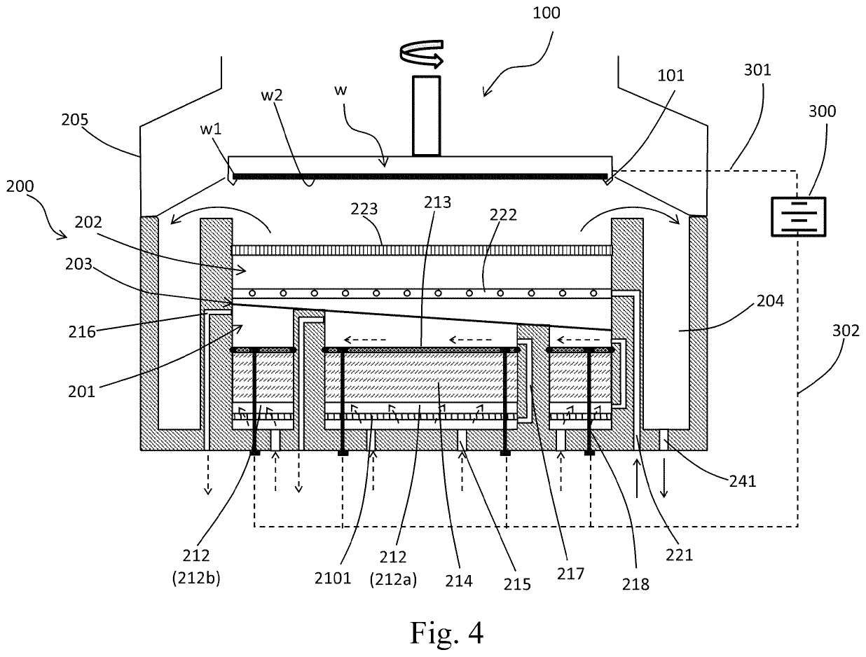

Please refer to FIG. 4, the present embodiment provides an electroplating apparatus. Compared with the first embodiment, the difference is that at least one anode region 212 is further provided with a rectifying plate 2101, and the rectifying plate 2101 is disposed between the anode liquid inlets 215 and the active anode 214 of the anode regions 212 where the rectifying plate 2101 is located. The rectifying plate 2101 can promote uniform dispersion of the anode liquid, so that metal ions can be uniformly and quickly conveyed to the substrate w, and the uniformity of electroplating can be improved.

It should be explained that when the active anode 214 is the metal granules, the metal granules may be laid flat on the rectifying plate 2101. At this time, the rectifying plate 2101 may use the conductive material (such as titanium metal), for supplying power to the active anode 214. Specifically, the rectifying plate 2101 may be electrically connected to the electroplating power supply 300 through the conductive posts 218, so as to supply power to the active anode 214.

### Embodiment 3

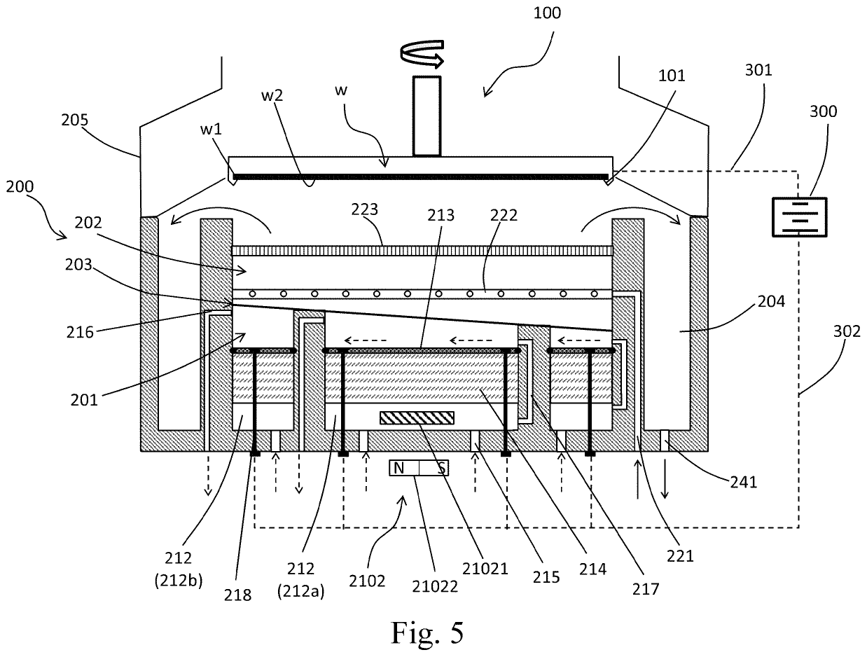

Please refer to FIG. 5, this embodiment provides an electroplating apparatus. Compared with the first embodiment, the difference is that at least one anode region 212 is further provided with a stirring member 2102. The stirring member 2102 is disposed between the active anode 214 and the anode liquid inlets 215 in the anode region 212 where the stirring member 2102 is located, and is used to uniformly disperse the anode liquid and improve the uniformity of electroplating. In this embodiment, without limiting the present invention, the stirring member 2102 is disposed in the anode region 212a located in the inner ring.

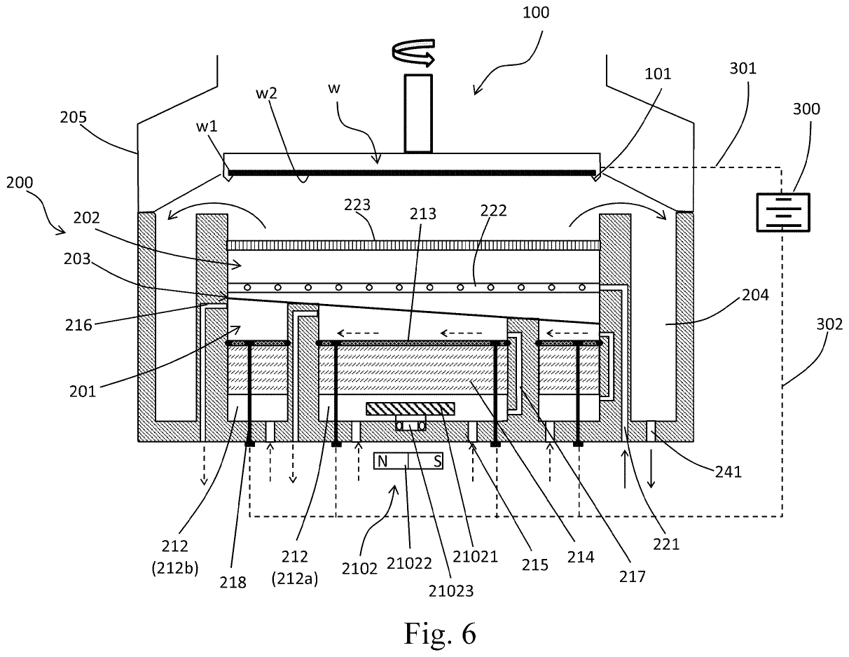

The stirring member 2102 is a magnetic stirrer and comprises a magnetic stirring bar 21021 and a magnetic generator 21022. The magnetic stirring bar 21021 is rotatably disposed inside the anode region 212 where the magnetic stirring bar 21021 is located. In one embodiment, as shown in FIG. 5, the magnetic stirring bar 21021 is freely placed inside the anode region 212 where the magnetic stirring bar 21021 is located. In the other embodiment, as shown in FIG. 6, the magnetic stirring bar 21021 is rotatably mounted to the bottom wall of the anode region 212 where the magnetic stirring bar 21021 is located by a bearing 21023.

The magnetic generator 21022 is disposed outside the anode region 212 where the magnetic generator is located, and is used to drive the magnetic stirring bar 21021 to rotate. The magnetic generator 21022 pushes the magnetic stirring bar 21021 to rotate by constantly changing the polarity of both ends, so that the anode liquid is uniformly dispersed.

### Embodiment 4

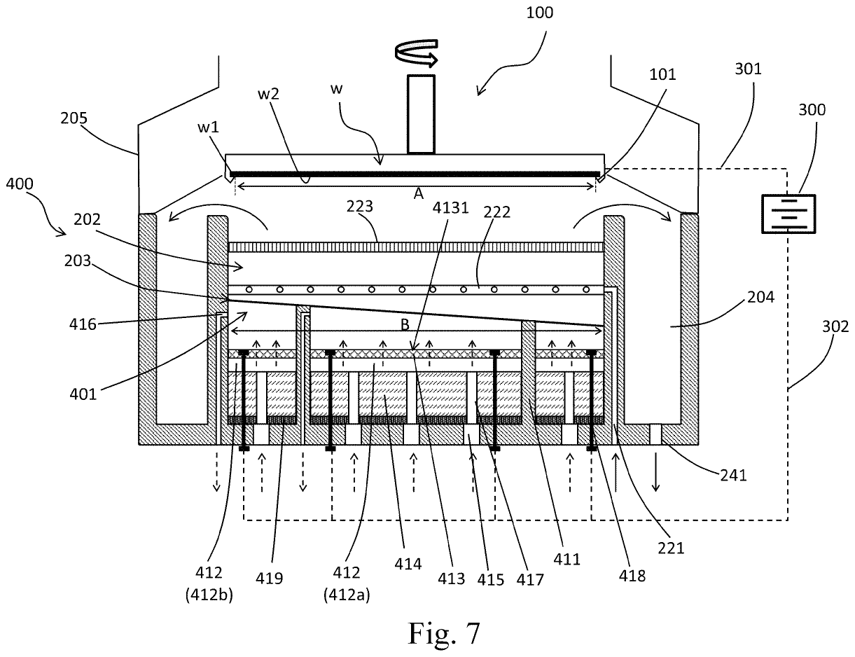

Please refer to FIG. 7, the present embodiment provides an electroplating apparatus, comprising a clamp 100 and an electroplating chamber 400. The clamp 100 is used to clamp the substrate w. The clamp 100 can drive the substrate w to perform actions such as rotation, inclination and lifting/lowering. The clamp 100 is provided with a sealing member 101 partitioning the surface of the substrate w into a first region w1 and a second region w2. The first region w1 is wrapped by the sealing member 101 and is not in contact with the electroplating liquid; The second region w2 is exposed outside the clamp 100 and is in contact with the electroplating liquid. Wherein, the second region w2 is the effective electroplating surface of the substrate w, and metal ions are deposited on the second region w2 when electroplating.

The electroplating chamber 400 comprises an anode chamber 401, a cathode chamber 202 disposed above the anode chamber 401, an ionic membrane 203 separating the anode chamber 401 and the cathode chamber 202, a peripheral chamber 204 surrounding the outside of the anode chamber 401 and the cathode chamber 202, and a protective cover 205 disposed above the peripheral chamber 204. The anode chamber 401 is used to store anode liquid, and the cathode chamber 202 is used to store cathode liquid, the anode liquid and cathode liquid are collectively referred to as the electroplating liquid.

The cathode chamber 202 is provided with a cathode liquid inlet 221, a cathode liquid supply pipe 222 and a diffusion plate 223. As shown by the solid arrows in FIG. 7, the cathode liquid enters the cathode liquid supply pipe 222 from the cathode liquid inlet 221, then is supplied to the cathode chamber 202 through the cathode liquid supply pipe 222, then overflows upward through the diffusion plate 223, and finally is discharged from the cathode liquid outlet 241 set at the bottom of the peripheral chamber 204. The diffusion plate 223 is disposed above the cathode liquid supply pipe 222, so as to uniformly disperse the cathode liquid in the cathode chamber 202. It can be understood that the cathode liquid outlet 241 may be communicated with the cathode liquid inlet 221 through an external circulation pipeline, so as to circulate and flow the cathode liquid.

The anode chamber 401 comprises at least one independent anode region 412, and each anode region 412 is provided with a meshed anode 413, an active anode 414, anode liquid inlets 415 and anode liquid outlets 416. In this embodiment, without limiting the present invention, a partition wall 411 is provided in the anode chamber 401, and the partition wall 411 separates the anode chamber 401 into two independent anode regions 412. The two anode regions 412 are arranged in the concentric circle. The active anode 414 is disposed below the meshed anode 413 and is continuously consumed during the electroplating process for the replenishment of metal ions. The active anode 414 may be the metal block or metal granules, such as the copper block or copper granules.

The meshed anode 413 is the inert anode and is made of the inert material, such as titanium metal (Ti). The surface of the meshed anode 413 may also have a gold (Au) or platinum (Pt) coating. During the electroplating process, the meshed anode 413 can provide the stable potential, and the meshed anode 413 is not consumed, and the distance between the meshed anode 413 and the substrate w can be maintained constant. Hence, the electric field generated by the meshed anode 413 on the substrate w does not change with the lapse of electroplating time, and the uniformity of electroplating can be improved to some extent.

A plurality of mesh holes are formed on the meshed anode 413, and the anode liquid can flow freely through the mesh holes. The mesh holes can be any shape such as circular holes, elliptical holes and polygonal holes. The meshed anode 413 is located below the substrate w, and is disposed opposite to the substrate w in parallel. The meshed anode 413 has the first surface 4131 disposed opposite to the effective electroplating surface of the substrate w. The plurality of mesh holes are formed on the first surface 4131. The first surface 4131 of the meshed anode 413 of the respective anode regions 412 collectively constitutes the electric field generating surface, and the size B of the electric field generating surface is equal to the size A of the effective electroplating surface (i.e., the second region w2) of the substrate w, so that the meshed anode 413 forms the uniform electric field on the effective electroplating surface of the substrate w. It is to be understood that “equal” herein allows for a certain degree of error, i.e., includes approximately equal cases.

The electroplating apparatus is further provided with an electroplating power supply 300 for controlling the current in the substrate w. The negative electrode of the electroplating power supply 300 is connected to the clamp 100 by a wire 301, so as to supply power to the substrate w in the clamp 100. Each anode region 412 is further provided with conductive posts 418 and a conductive plate 419, and the conductive posts 418 and the conductive plate 419 may be selected from titanium metal (Ti). The conductive plate 419 may be directly mounted at the bottom of the anode regions 412 where the conductive plate 419 is located, or may be disposed at an interval from the bottom of the anode regions 412 where the conductive plate 419 is located, and the interval forms a space for the anode liquid to flow. The active anode 414 is disposed on the conductive plate 419. The conductive posts 418 are electrically connected to the meshed anode 413 and the conductive plate 419. The positive electrode of the electroplating power supply 300 is connected to the conductive posts 418 by a lead 302, so as to supply power to the meshed anode 413 and the active anode 414 disposed on the conductive plate 419.

In the above description, the meshed anode 413 and the active anode 414 share the conductive posts 418 as an embodiment to explain. It can be understood that in other embodiments, the meshed anode 413 and the active anode 414 may each independently configure the conductive posts 418 electrically connected to the electroplating power supply 300, so that the electroplating power supply 300 can independently control the meshed anode 413 and the active anode 414, respectively. Besides, it should be explained that the electroplating power supply 300 may independently control each anode, or may synchronously control the part of the anode of each anode. For example, the electroplating power supply 300 may independently control the current (or voltage) in the meshed anode 413 and the active anode 414 of the same anode regions 412, or may synchronously control the current (or voltage) in the meshed anode 413 and the active anode 414 of the same anode regions 412.

Each anode region 412 is provided with at least one anode liquid inlet 415, for supplying anode liquid to the anode regions 412. In FIG. 7, three anode liquid inlets 415 are disposed at the bottom of the anode region 412a of the inner ring, and two anode liquid inlets 415 are disposed at the bottom of the anode region 412b of the outer ring. In this embodiment, the active anode 414 is the metal block, and the active anode 414 and the conductive plate 419 below the active anode 414 have through holes 417, and the through holes 417 are communicated with the anode liquid inlets 415 for the flow of anode liquid. Specifically, as shown in FIG. 7, the anode liquid inlets 415 directly penetrate the active anode 414 and the conductive plate 419 below the active anode 414, so as to form the above-described through holes 417. The dashed arrows in FIG. 7 show the flow direction of anode liquid in the anode regions 412. The anode liquid immerses the active anode 414 upward from the anode liquid inlets 415, and then flows to the anode liquid outlets 416 through the meshed anode 413.

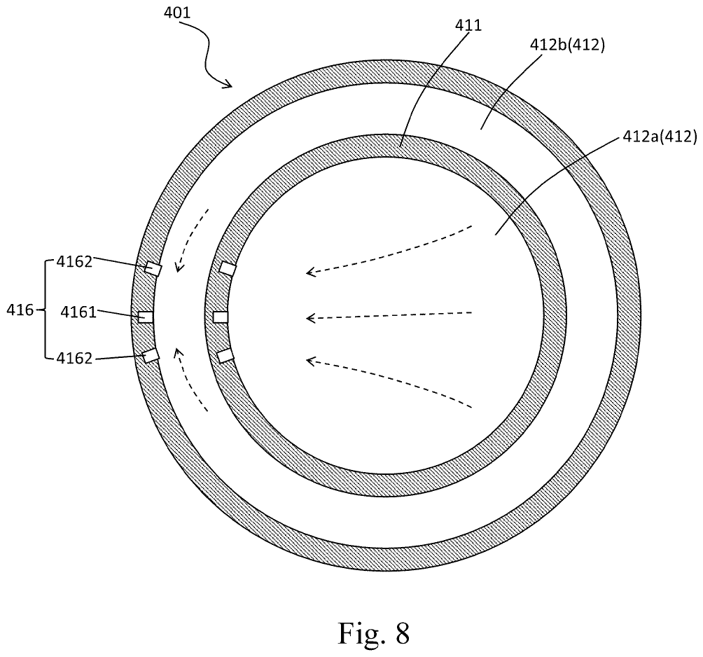

Each anode region 412 is provided with at least one anode liquid outlet 416, for discharging anode liquid from the anode regions 412. One of the at least one anode liquid outlets 416 configured for each anode region 412 is located at the highest point of the anode region 412 where the anode liquid outlet 416 is located. In the preferred embodiment, referring to FIG. 8, each anode region 412 comprises a first anode liquid outlet 4161 and at least a pair of second anode liquid outlets 4162. Wherein, the first anode liquid outlet 4161 is located at the highest point (vertical direction in FIG. 7) of the anode regions 412 where the anode liquid outlet 4161 is located, and the second anode liquid outlets 4162 are arranged in pairs on both sides of the first anode liquid outlet 4161 of the anode regions 412 where the second anode liquid outlets 4162 are located. In FIG. 8, each of the anode regions 412a and 412b is provided with a first anode liquid outlet 4161 and a pair of second anode liquid outlets 4162. The dashed arrows in FIG. 8 show the flow direction of anode liquid above the meshed anode 413, specifically, above the meshed anode 413, the anode liquid flows smoothly to the anode liquid outlets 416 generally along one direction.

It should be noted that FIG. 8 is merely an embodiment, and is not used to limit the number of anode liquid outlets 416, and the number of anode liquid outlets 416 can be reasonably optimized according to the process flow rate of anode liquid and the parameters of flow field distribution.

### Embodiment 5

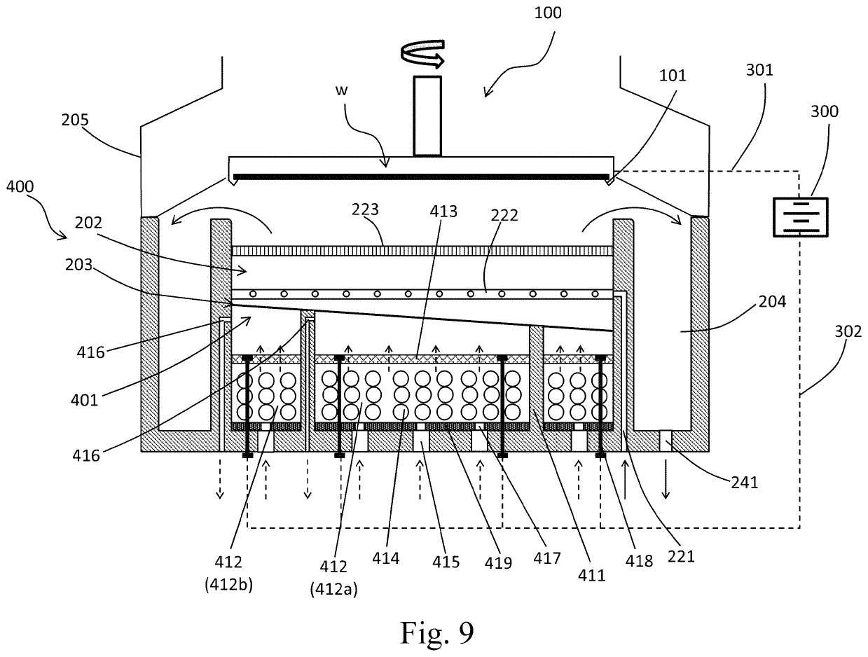

Please refer to FIG. 9, this embodiment proposes an electroplating apparatus. Compared with the fourth embodiment, the difference is that the active anode 414 is the metal granules. The particulate active anode 414 is laid flat on the conductive plate 419.

Since the anode liquid can flow freely through the gaps between metal granules, in this embodiment, only the conductive plate 419 is provided with through holes 417 for the flow of anode liquid. The through holes 417 may be formed by the anode liquid inlets 415 directly penetrating the conductive plate 419. The dashed arrows in FIG. 9 indicate the flow direction of anode liquid in the anode regions 412. As shown in FIG. 9, the anode liquid flows upward from the anode liquid inlets 415 into the gaps between metal granules, then immerses metal granules, then flows upward through the meshed anode 413, and finally flows out through the anode liquid outlets 416.

### Embodiment 6

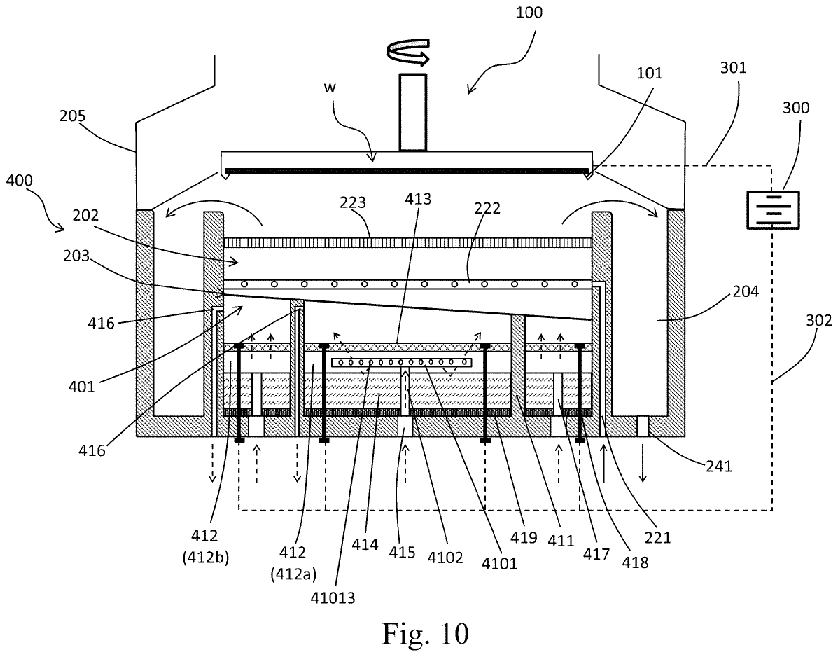

Please refer to FIG. 10, this embodiment proposes an electroplating apparatus. Compared with the fourth embodiment, the difference is that at least one anode region 412 is further provided with a fluid dispersion pipe 4101 and an anode liquid inlet pipe 4102. The fluid dispersion pipe 4101 is located above the active anode 414 of the anode region 412 where the fluid dispersion pipe 4101 is located, and communicates with the anode liquid inlet 415 of the anode region 412 where the fluid dispersion pipe 4101 is located through the anode liquid inlet pipe 4102, so as to uniformly disperse the anode liquid. In this embodiment, without limiting the present invention, the fluid dispersion pipe 4101 is disposed in the anode region 412a located in the inner ring.

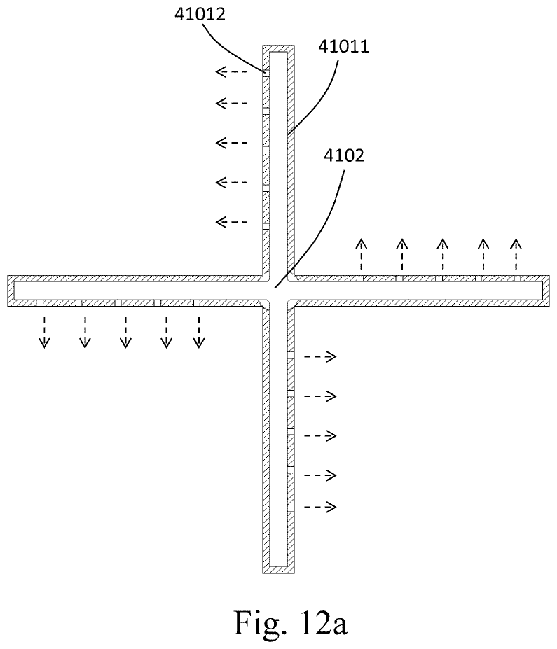

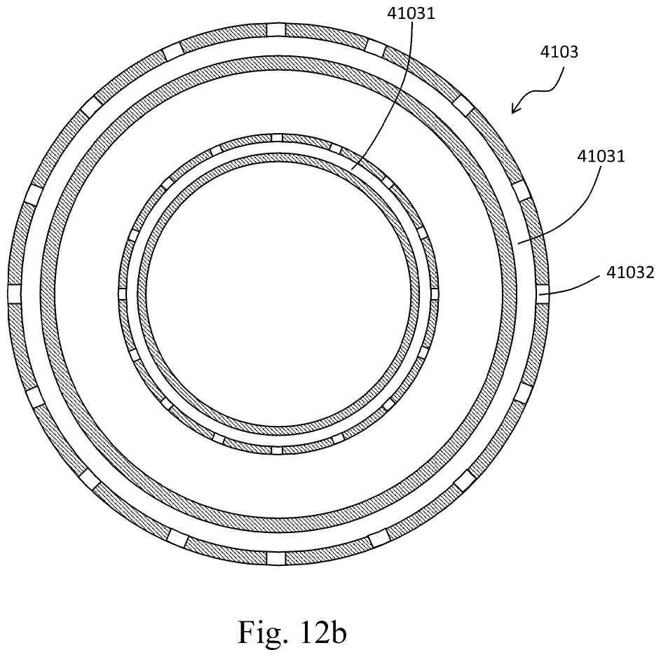

In the present embodiment, as shown in FIG. 12a, the fluid dispersion pipe 4101 comprises a plurality of branch pipes 41011. The plurality of branch pipes 41011 are radially distributed around the anode liquid inlet pipe 4102 and communicate with the anode liquid inlet pipe 4102. The branch pipes 41011 have straight pipe shapes. A plurality of ejection ports 41012 are set along the longitudinal direction of the branch pipes 41011, and the ejection ports 41012 are disposed inclined downward. In order to further enhance the dispersion effect of the fluid dispersion pipe 4101 on the anode liquid, as shown in FIG. 12a, each of the plurality of branch pipes 41011 is provided with a row of ejection ports 41012 along the longitudinal direction of the branch pipes 41011, and the plurality of rows of ejection ports 41012 set the orientation of the ejection ports 41012 in the same rotational direction (as in the counterclockwise direction in FIG. 12a).

FIG. 12b shows another modification of the fluid dispersion pipe. As shown in FIG. 12b, the fluid dispersion tube 4103 comprises at least one annular tube 41031, and the annular tube 41031 is provided with a plurality of discharge ports 41032. In FIG. 12b, the fluid dispersion tube 4103 comprises two annular tubes 41031 arranged in the concentric circle.

It should be noted that the specific form of the fluid dispersion pipe can be reasonably designed according to parameters such as the shape and size of the anode regions where the fluid dispersion pipe is located, and is not limited to the embodiments shown in FIGS. 12a and 12b. Besides, different anode regions may adopt different forms of fluid dispersion pipes, for example, the fluid dispersion pipe 4101 is adopted in the anode region 412a of the inner ring, and the fluid dispersion tube 4103 is adopted in the anode region 413b of the outer ring.

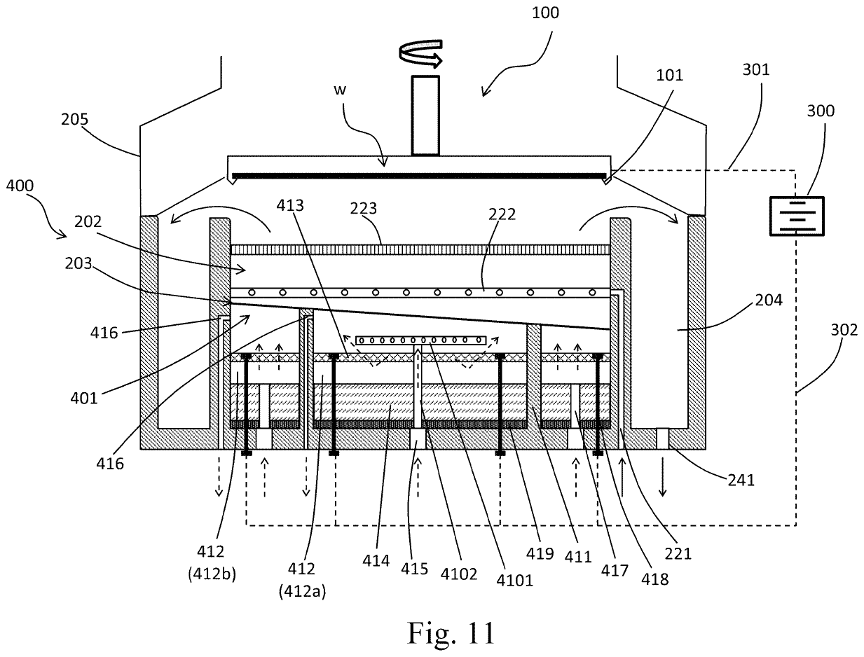

The fluid dispersion pipe 4101 is located above the active anode 414. In one embodiment, the fluid dispersion pipe 4101 is located between the active anode 414 and the meshed anode 413 as shown in FIG. 10. In the anode region 412a located in the inner ring, the anode liquid is ejected downward from the ejection ports 41012 to flush the active anode 414 and then flows upward through the meshed anode 413 to the anode liquid outlets 416 as shown by dashed arrows in FIG. 10. In the other embodiment, the fluid dispersion pipe 4101 is located above the meshed anode 413 as shown in FIG. 11. In the anode region 412a located in the inner ring, the anode liquid is ejected downward from the ejection ports 41012 to sequentially flush the meshed anode 413 and the active anode 414 as shown by the dashed arrows in FIG. 11, and then flows through the meshed anode 413 to the anode liquid outlets 416.

### Embodiment 7

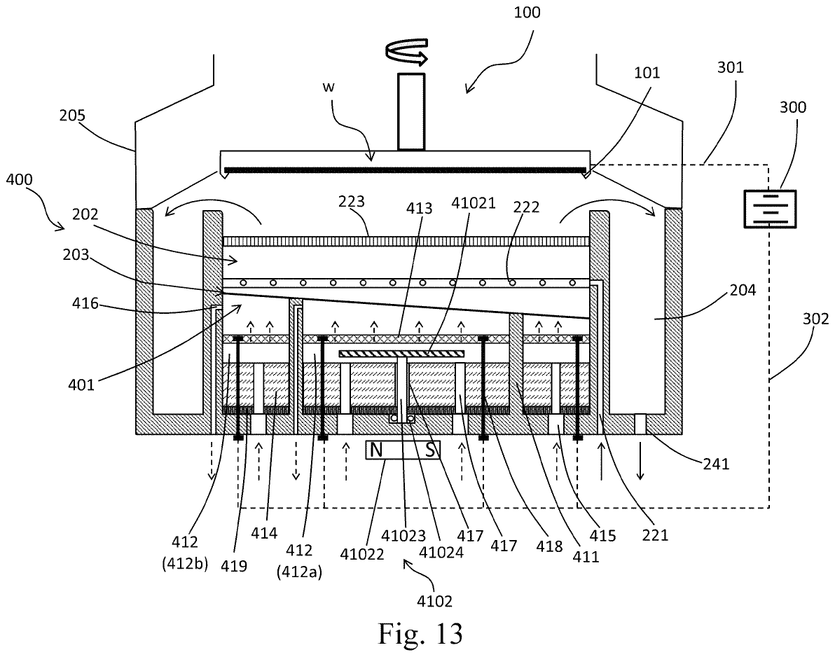

Please refer to FIG. 13, this embodiment proposes an electroplating apparatus. Compared with the fourth embodiment, the difference is that at least one anode region 412 is further provided with a stirring member 4102 for uniformly dispersing the anode liquid. In this embodiment, without limiting the present invention, the stirring member 4102 is disposed in the anode region 412a located in the inner ring.

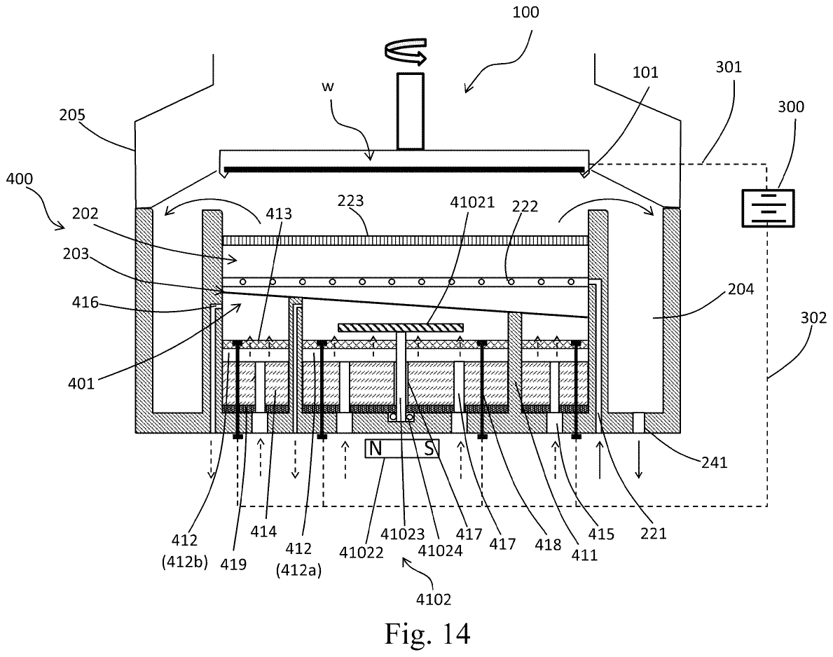

As shown in FIG. 13, the stirring member 4102 is a magnetic stirrer and comprises a magnetic stirring bar 41021 and a magnetic generator 41022. The magnetic stirring bar 41021 is rotatably mounted inside the anode region 412 where the magnetic stirring bar is located. Specifically, the magnetic stirring bar 41021 is mounted on the upper end of a rotating shaft 41023, the lower end of the rotating shaft 41023 passes through the through holes 417 on the active anode 414 and the conductive plate 419, and is rotatably mounted on the bottom wall of the anode region 412 by a bearing 41024. The magnetic generator 41022 is disposed outside the anode region 412 where the magnetic generator 41022 is located, and is used to drive the magnetic stirring bar 41021 to rotate. The magnetic stirring bar 41021 is located above the active anode 414. In one embodiment, as shown in FIG. 13, the magnetic stirring bar 41021 is located between the meshed anode 413 and the active anode 414. In the other embodiment, as shown in FIG. 14, the magnetic stirring bar 41021 is located above the meshed anode 413.

### Embodiment 8

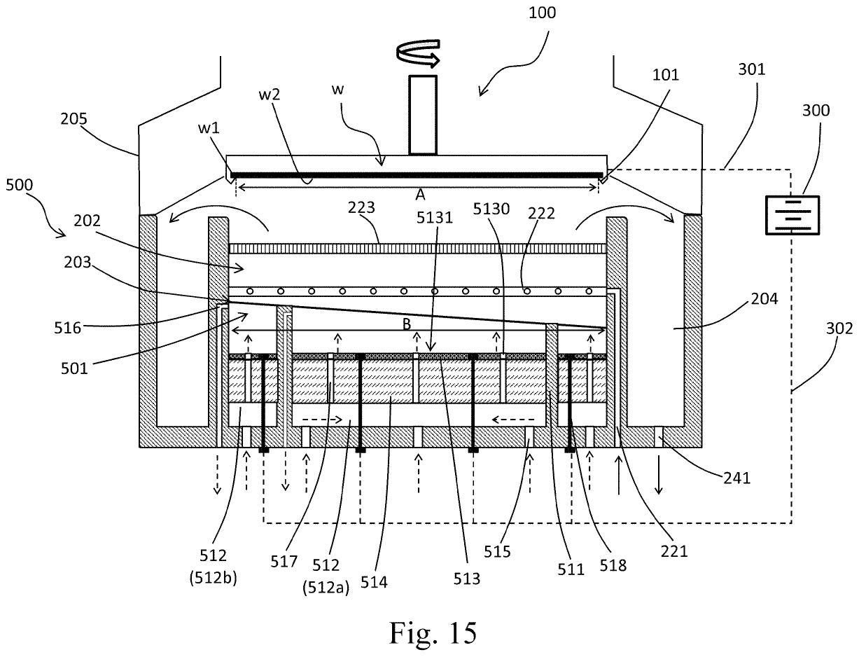

Please refer to FIG. 15, the present embodiment provides an electroplating apparatus, comprising a clamp 100 and an electroplating chamber 500. The clamp 100 is used for clamping the substrate w. The clamp 100 can drive the substrate w to perform actions such as rotation, inclination and lifting/lowering. The clamp 100 is provided with a sealing member 101 partitioning the surface of the substrate w into a first region w1 and a second region w2. The first region w1 is wrapped by the sealing member 101 and is not in contact with the electroplating liquid; The second region w2 is exposed outside the clamp 100 and is in contact with the electroplating liquid. Wherein, the second region w2 is the effective electroplating surface of the substrate w, and metal ions are deposited on the second region w2 when electroplating.

The electroplating chamber 500 comprises an anode chamber 501, a cathode chamber 202 disposed above the anode chamber 501, an ionic membrane 203 separating the anode chamber 501 and the cathode chamber 202, a peripheral chamber 204 surrounding the outside of the anode chamber 501 and the cathode chamber 202, and a protective cover 205 disposed above the peripheral chamber 204. The anode chamber 501 is used for storing anode liquid, and the cathode chamber 202 is used for storing cathode liquid, the anode liquid and cathode liquid are collectively referred to as the electroplating liquid.

The cathode chamber 202 is provided with a cathode liquid inlet 221, a cathode liquid supply pipe 222 and a diffusion plate 223. As shown by the solid arrows in FIG. 15, the cathode liquid enters the cathode liquid supply pipe 222 through the cathode liquid inlet 221, then is supplied to the cathode chamber 202 through the cathode liquid supply pipe 222, then overflows upward to the peripheral chamber 204 through the diffusion plate 223, and finally is discharged from the cathode liquid outlet 241 set at the bottom of the peripheral chamber 204. The diffusion plate 223 is disposed above the cathode liquid supply pipe 222, so as to uniformly disperse the cathode liquid in the cathode chamber 202. It can be understood that the cathode liquid outlet 241 may be communicated with the cathode liquid inlet 221 through the external circulation pipeline, so as to circulate and flow the cathode liquid.

The anode chamber 501 comprises at least one independent anode region 512, and each anode region 512 is provided with a perforated anode 513, an active anode 514, anode liquid inlets 515 and anode liquid outlets 516. In this embodiment, without limiting the present invention, a partition wall 511 is provided in the anode chamber 501. The partition wall 511 separates the anode chamber 501 into two independent anode regions 512, and the two anode regions 512 are arranged in the concentric circle. The active anode 514 is disposed below the perforated anode 513 for the replenishment of metal ions.

The perforated anode 513 is the inert anode and is made of the inert material, such as titanium metal (Ti). The surface of the perforated anode 513 may also have a gold (Au) or platinum (Pt) coating. During the electroplating process, the perforated anode 513 can provide the stable potential, and the perforated anode 513 is not consumed, and the distance between the perforated anode 513 and the substrate w can be maintained constant. Hence, the electric field generated by the perforated anode 513 on the substrate w does not change with the lapse of electroplating time, and the uniformity of electroplating can be improved to some extent.

The perforated anode 513 is formed with perforations 5130 for free flow of the anodic liquid. The perforated anode 513 is located below the substrate w, and is disposed opposite to the substrate w in parallel. The perforated anode 513 has a first surface 5131 disposed opposite to the effective electroplating surface of the substrate w. Preferably, the perforations 5130 are perpendicular to the substrate w.

The first surface 5131 of the perforated anode 513 of the respective anode regions 512 collectively constitutes the electric field generating surface, and the size B of the electric field generating surface is equal to the size A of the effective electroplating surface (i.e., the second region w2) of the substrate w, so that the perforated anode 513 forms the uniform electric field on the effective electroplating surface of the substrate w. It is to be understood that “equal” herein allows for a certain degree of error, i.e., includes approximately equal cases.

The electroplating apparatus is further provided with the electroplating power supply 300 for controlling the current in the substrate w. The negative electrode of the electroplating power supply 300 is connected to the clamp 100 through the wire 301, so as to supply power to the substrate w in the clamp 100. Each anode region 512 is further provided with conductive posts 518, and the conductive posts 518 may be selected from titanium metal (Ti). The electroplating power supply 300 is connected to the conductive posts 518 by the lead 302, and the conductive posts 518 are electrically connected to the perforated anode 513 and the active anode 514. The electroplating power supply 300 supplies power to the perforated anode 513 and the active anode 514 through the conductive posts 518.

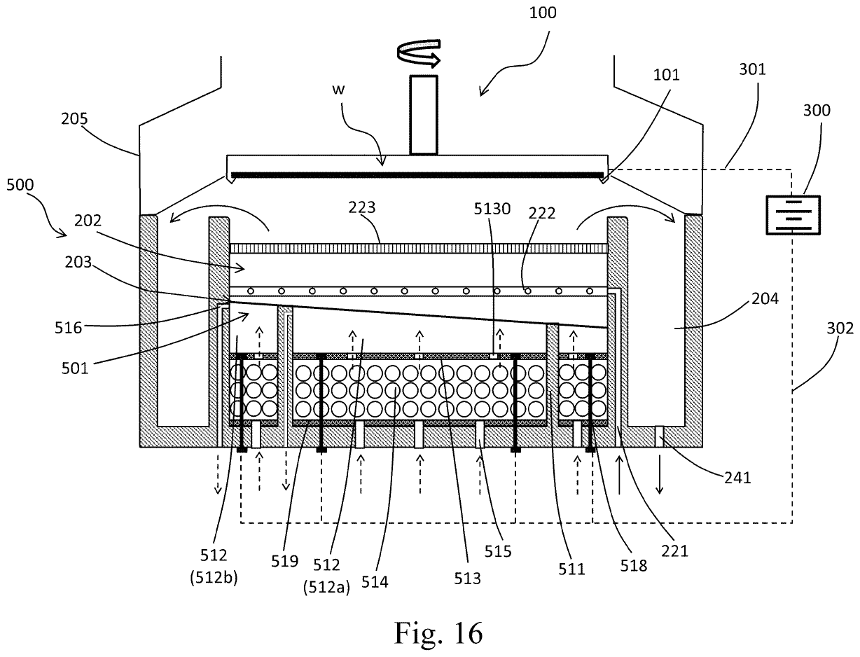

In one embodiment, as shown in FIG. 15, the active anode 514 is the metal block and is directly inverted below the perforated anode 513. At this time, the perforated anode 513 can be electrically connected to the electroplating power supply 300 through the conductive posts 518, and the perforated anode 513 can also serve as the conductive plate 519 to supply power to the active anode 514. In the other embodiment, as shown in FIG. 16, the active anode 514 may be the metal granules laid flat on the conductive plate 519 disposed below the perforated anode 513. At this time, the perforated anode 513 is electrically connected to the electroplating power supply 300 through the conductive posts 518, and the conductive plate 519 is electrically connected to the electroplating power supply 300 through the conductive posts 518, so as to supply power to the active anode 514.

In the above description, the perforated anode 513 and the active anode 514 share the conductive posts 518 as an embodiment to explain, it can be understood that in other embodiments, the perforated anode 513 and the active anode 514 may each independently configure the conductive posts 518 electrically connected to the electroplating power supply 300, so that the electroplating power supply 300 can independently control the perforated anode 513 and the active anode 514, respectively. Besides, it should be explained that the electroplating power supply 300 may independently control each anode, or may synchronously control the part of the anode in each anode. For example, the electroplating power supply 300 may independently control the current (or voltage) in the perforated anode 513 and the active anode 514 of the same anode regions 512, or may synchronously control the current (or voltage) in the perforated anode 513 and the active anode 514 of the same anode regions 512. Each anode region 512 is provided with at least one anode liquid inlet 515, for supplying anode liquid to the anode regions 512. In FIG. 15, three anode liquid inlets 515 are disposed at the bottom of the anode region 512a of the inner ring, and two anode liquid inlets 515 are disposed at the bottom of the anode region 512b of the outer ring. As indicated by dashed arrows in FIG. 15, the anode liquid is supplied from the anode liquid inlets 515 to each anode region 512 from bottom to top, in each anode region 512, the anode liquid flows through the active anode 514 and the perforated anode 513 sequentially, and finally flows to the anode liquid outlets 516.

In one embodiment, as shown in FIG. 15, the active anode 514 is the metal block, and through holes 517 are formed in the metal block. The through holes 517 can communicate the anode liquid inlets 515 with the perforations 5130 of the perforated anode 513, so as to allow the anode liquid to flow. In the other embodiment, as shown in FIG. 16, the active anode 514 is the metal granules with gaps between metal granules. The gaps can communicate the anode liquid inlets 515 with the perforations 5130 of the perforated anode 513 for the flow of anode liquid. It can be understood that, in other embodiments, a slit may also be reserved between the side wall of the perforated anode 513 and the side wall of the anode regions 512 where the perforated anode 513 is located as a channel for the flow of anode liquid. Similarly, when the active anode 514 is the metal block, the slit may be reserved between the side wall of the active anode 514 and the side wall of the anode regions 512 where the active anode 514 is located as the channel for the flow of anode liquid.

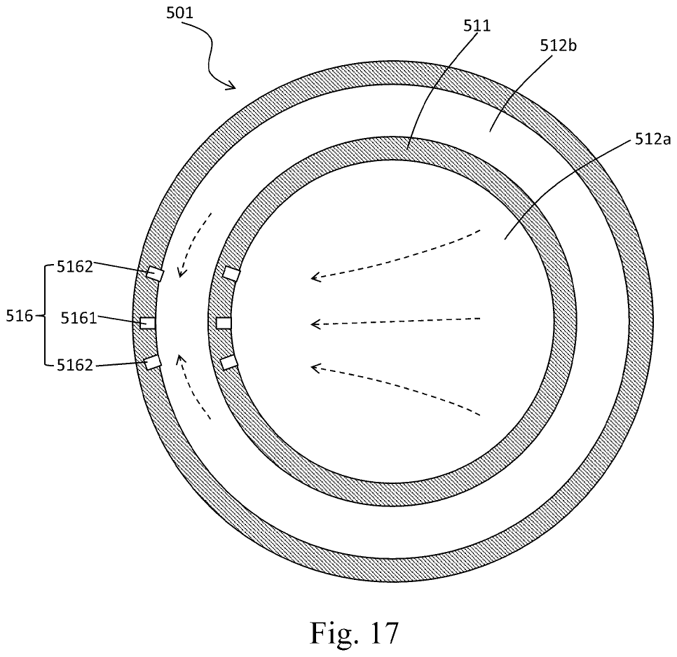

Each anode region 512 is provided with at least one anode liquid outlet 516, for discharging anode liquid from the anode regions 512. As shown in FIG. 15, in each anode region 512, the anode liquid outlets 516 are disposed above the perforated anode 513. One of the at least one anode liquid outlets 516 configured for each anode region 512 is located at the highest point of the anode region 512 where the anode liquid outlet 516 is located. In the preferred embodiment, referring to FIG. 17, each anode region 512 comprises a first anode liquid outlet 5161 and at least a pair of second anode liquid outlets 5162, wherein the first anode liquid outlet 5161 is located at the highest point of the anode regions 512 where the first anode liquid outlet 5161 is located, and the second anode liquid outlets 5162 are arranged in pairs on both sides of the first anode liquid outlet 5161 of the anode regions 512 where the second anode liquid outlets 5162 are located. In FIG. 17, each of the anode regions 512a and 512b is provided with a first anode liquid outlet 5161 and a pair of second anode liquid outlets 5162. The dashed arrows in FIG. 17 show the flow direction of anode liquid above the perforated anode 513. Specifically, above the perforated anode 513, the anode liquid flows smoothly to the anode liquid outlets 516 generally along one direction.

It should be explained that FIG. 17 is merely an embodiment, and is not used to limit the number of anode liquid outlets 516, and the number of anode liquid outlets 516 can be reasonably optimized according to the process flow rate of anode liquid and the parameters of flow field distribution.

### Embodiment 9

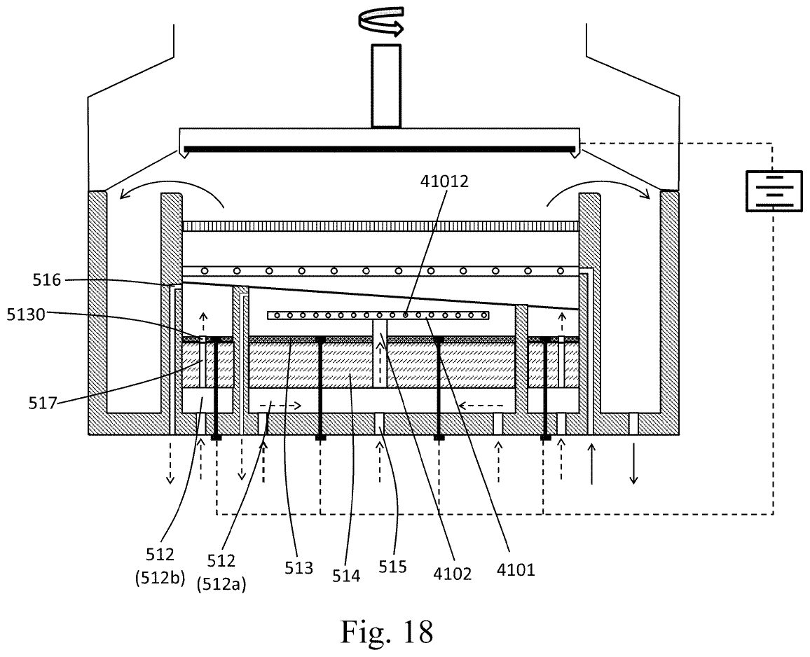

Please refer to FIG. 18, this embodiment proposes an electroplating apparatus. Compared with the eighth embodiment, the difference is that at least one anode region 512 is further provided with a fluid dispersion pipe 4101 and an anode liquid inlet pipe 4102. The fluid dispersion pipe 4101 is located above the perforated anode 513 of the anode region 512 where the fluid dispersion pipe 4101 is located, and communicates with the anode liquid inlet 515 of the anode region 512 where the fluid dispersion pipe 4101 is located through the anode liquid inlet pipe 4102, so as to uniformly disperse the anode liquid. In this embodiment, without limiting the present invention, the fluid dispersion pipe 4101 is disposed in the anode region 512a located in the inner ring.

With reference to FIG. 12a, the fluid dispersion pipe 4101 comprises a plurality of branch pipes 41011. The plurality of branch pipes 41011 are radially distributed around the anode liquid inlet pipe 4102 and communicate with the anode liquid inlet pipe 4102. The branch pipes 41011 have straight pipe shapes, a plurality of ejection ports 41012 are set along the longitudinal direction of the ejection ports 41012, and the ejections ports 41012 are disposed inclined downward. In the present embodiment, as shown in FIG. 18, the anode liquid inlet pipe 4102 is mounted at the position of perforations 5130 of the perforated anode 513, and one end of the anode liquid inlet pipe 4102 is located above the perforated anode 513 and communicates with the plurality of branch pipes 41011, and the other end of the anode liquid inlet pipe 4102 is located below the perforated anode 513 and communicates with the anode liquid inlet 515.

In order to further enhance the dispersion effect of the fluid dispersion pipe 4101 on the anode liquid, as shown in FIG. 12a, each of the plurality of branch pipes 41011 is provided with a row of ejection ports 41012 along the longitudinal direction of the branch pipes 41011, and the plurality of rows of ejection ports 41012 set the orientation of the ejection ports 41012 in the same rotational direction (as in the counterclockwise direction).

FIG. 12b shows another modification of the fluid dispersion pipe. As shown in FIG. 12b, the fluid dispersion tube 4103 comprises at least one annular tube 41031, and the annular tube 41031 is provided with the plurality of discharge ports 41032. In FIG. 12b, the fluid dispersion tube 4103 comprises two annular tubes 41031 arranged in the concentric circle.

### Embodiment 10

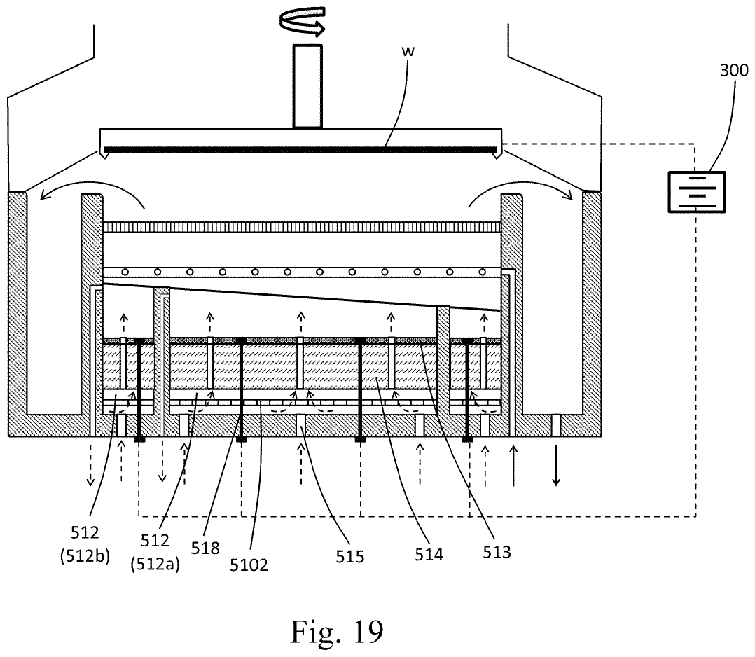

Please refer to FIG. 19, the present embodiment provides an electroplating apparatus. Compared with the eighth embodiment, the difference is that at least one anode region 512 is further provided with a rectifying plate 5102, and the rectifying plate 5102 is arranged between the anode liquid inlets 515 and the active anode 514 of the anode regions 512 where the rectifying plate 5102 is located. The rectifying plate 5102 can promote the uniform dispersion of anode liquid, and uniformly and rapidly convey metal ions to the substrate w, thereby improving the uniformity of electroplating.

It should be explained that when the active anode 514 is the metal granules, the metal granules may be laid flat on the rectifying plate 5102. At this time, the rectifying plate 5102 may use the conductive material (such as titanium metal) for supplying power to the active anode 514. Specifically, the rectifying plate 5102 may be electrically connected to the electroplating power supply 300 through the conductive posts 518, so as to supply power to the active anode 514.

### Embodiment 11

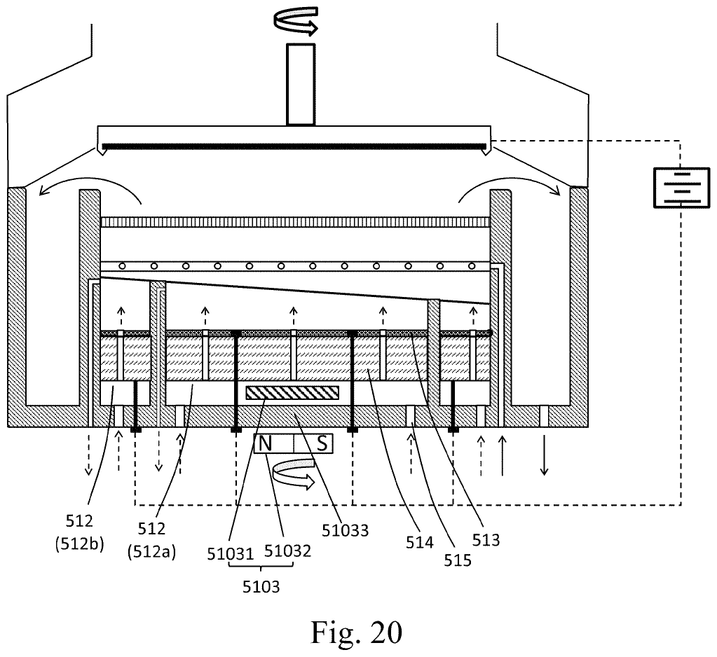

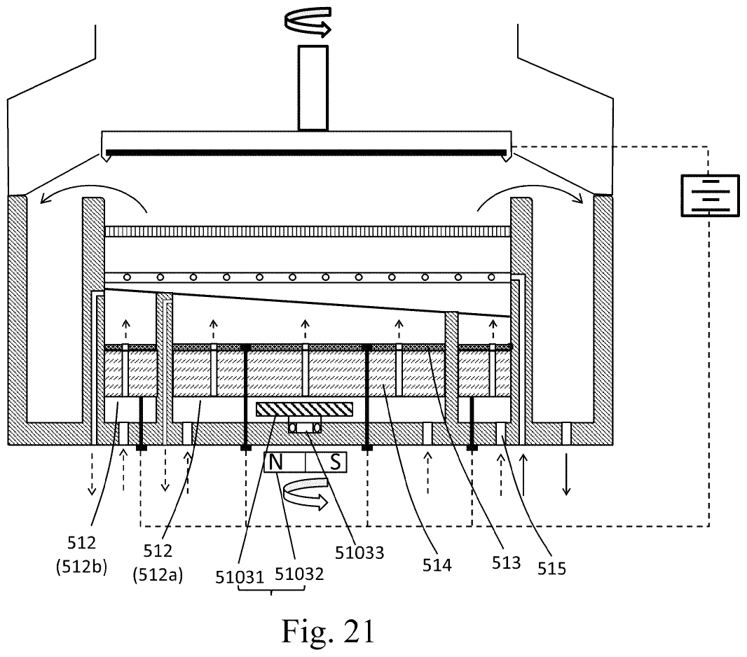

Please refer to FIG. 20, this embodiment proposes an electroplating apparatus. Compared with the eighth embodiment, the difference is that at least one anode region 512 is further provided with a stirring member 5103. The stirring member 5103 is disposed between the anode liquid inlets 515 and the active anode 514 in the anode region 512 where the stirring member 5103 is located, and is used to uniformly disperse the anode liquid. In the present embodiment, without limiting the present invention, the stirring member 5103 is disposed in the anode region 512a located in the inner ring. The stirring member 5103 is a magnetic stirrer and comprises a magnetic stirring bar 51031 and a magnetic generator 51032. The magnetic stirring bar 51031 is rotatably disposed inside the anode region 512 where the magnetic stirring bar 51031 is located. Specifically, the magnetic stirring bar 51031 is rotatably disposed between the anode liquid inlets 515 and the active anode 514 of the anode region 512 where the magnetic stirring bar 51031 is located. In one embodiment, as shown in FIG. 20, the magnetic stirring bar 51031 is freely placed inside the anode region 512 where the magnetic stirring bar 51031 is located. In the other embodiment, as shown in FIG. 21, the magnetic stirring bar 51031 is rotatably mounted to the bottom wall of the anode region 512 where the magnetic stirring bar 51031 is located by the bearing 51033.

The magnetic generator 51032 is disposed outside the anode region 512 where the magnetic generator 51032 is located, and is used to drive the magnetic stirring bar 51031 to rotate. The magnetic generator 51032 pushes the magnetic stirring bar 51031 to rotate by constantly changing the polarity of both ends, so as to uniformly disperse the anode liquid.

The above embodiments are merely illustrative of the principles and efficacies of the present invention, and are not intended to limit the present invention. Anyone skilled in the art can make modifications or changes to the above-described embodiments without departing from the spirit and scope of the present invention. Therefore, all equivalent modifications or changes made by those of ordinary skill in the art without departing from the spirit and technical ideas disclosed of the present invention should still be covered by the claims of the present invention.

1. An electroplating apparatus, comprising:
a clamp, for clamping a substrate;
an anode chamber, including at least one independent anode region, each anode region being configured with:
a solid anode, being an inert anode, and disposed below the substrate and disposed opposite to the substrate in parallel;
an active anode, disposed below the solid anode, for replenishing metal ions;
at least one anode liquid inlet, for supplying anode liquid to the anode region;
at least one anode liquid outlet, for discharging anode liquid from the anode region;
at least one internal fluid channel, disposed in the side wall of the anode region, for guiding anode liquid to flow from the anode liquid inlet to the anode liquid outlet.

2. The electroplating apparatus according to claim 1, wherein the solid anode has a first surface parallel to the substrate, the first surface of the solid anode of the respective anode regions collectively constitutes an electric field generating surface, the size of the electric field generating surface is equal to the size of the effective electroplating surface of the substrate.

3. The electroplating apparatus according to claim 1, wherein the solid anode is in sealing contact with the wall surface of the anode region where the solid anode is located.

4. The electroplating apparatus according to claim 1, wherein at least one anode liquid outlet arranged in each anode region comprises a first anode liquid outlet and at least a pair of second anode liquid outlets, the first anode liquid outlet is located at the highest point of the anode region where the first anode liquid outlet is located, and the second anode liquid outlets are arranged in pairs on both sides of the first liquid outlet of the anode region where the second anode liquid outlets are located.

5. The electroplating apparatus according to claim 1, wherein the anode liquid inlet is disposed at the bottom of each anode region, for causing the anode liquid to flush the active anode from bottom to top.

6. The electroplating apparatus according to claim 5, wherein at least one anode region is further provided with a rectifying plate, and the rectifying plate is arranged between the anode liquid inlet and the active anode of the anode region where the rectifying plate is located.

7. The electroplating apparatus according to claim 5, wherein at least one anode region is further provided with a stirring member, the stirring member is disposed between the anode liquid inlet and the active anode of the anode region where the stirring member is located.

8. The electroplating apparatus according to claim 7, the stirring member comprising:
a magnetic stirring bar, arranged inside the anode region where the magnetic stirring bar is located;
a magnetic generator, arranged outside the anode region where the magnetic generator is located, being used to drive the magnetic stirring bar to rotate.

9. The electroplating apparatus according to claim 8, wherein the magnetic stirring bar is freely placed inside the anode region where the magnetic stirring bar is located, or the magnetic stirring bar is rotatably mounted on the bottom wall of the anode region where the magnetic stirring bar is located by a bearing.

10.-12. (canceled)

13. An electroplating apparatus, comprising:
a clamp, for clamping a substrate;
an anode chamber, including at least one independent anode region, each anode region being configured with:
an inert anode, the inert anode including a meshed anode or a perforated anode, the inert anode being disposed below the substrate and disposed opposite to the substrate in parallel;
an active anode, disposed below the inert anode for replenishing metal ions;
at least one anode liquid inlet, for supplying anode liquid to the anode region;
at least one anode liquid outlet, for discharging anode liquid from the anode region.

14. The electroplating apparatus according to claim 13, wherein the inert anode has a first surface parallel to the substrate, the first surface of the inert anode of the respective anode regions collectively constitutes an electric field generating surface, the size of the electric field generating surface is equal to the size of the effective electroplating surface of the substrate.

15. The electroplating apparatus according to claim 13, wherein at least one anode liquid outlet arranged in each anode region comprises a first anode liquid outlet and at least a pair of second anode liquid outlets, the first anode liquid outlet is located at the highest point of the anode region where the first anode liquid outlet is located, and the second anode liquid outlets are arranged in pairs on both sides of the first anode liquid outlet of the anode region where the second anode liquid outlets are located.

16. The electroplating apparatus according to claim 13, wherein at least one anode region is further configured with a stirring member, comprising:
a magnetic stirring bar, located above the active anode of the anode region where the magnetic stirring bar is located, and rotatably connected to the bottom wall of the anode region by a bearing;
a magnetic generator, arranged outside the anode region where the magnetic generator is located, being used to drive the magnetic stirring bar to rotate.

17. The electroplating apparatus according to claim 13, wherein at least one anode region is further provided with a fluid dispersion pipe and an anode liquid inlet pipe, the fluid dispersion pipe is located above the active anode in the anode region where the fluid dispersion pipe is located, and communicates with the anode liquid inlet of the anode region where the fluid dispersion pipe is located through the anode liquid inlet pipe, so as to uniformly disperse the anode liquid.

18. The electroplating apparatus according to claim 17, wherein the fluid dispersion pipe comprises a plurality of branch pipes having straight pipe shapes, and a plurality of ejection ports are set, the plurality of branch pipes are radially distributed around the anode liquid inlet pipe and communicate with the anode liquid inlet pipe.

19. The electroplating apparatus according to claim 18, wherein the ejection ports are disposed inclined downward.

20. The electroplating apparatus according to claim 18, wherein each of the plurality of branch pipes is provided with a row of ejection ports along the longitudinal direction of the branch pipes, and the plurality of rows of ejection ports set the orientation of the ejection ports in the same rotational direction.

21.-23. (canceled)

24. An electroplating apparatus, comprising:
a clamp, for clamping a substrate;
an anode chamber, including at least one independent anode region, each anode region being configured with:
a perforated anode, having a perforation formed thereon, and being an inert anode, disposed below the substrate and disposed opposite to the substrate in parallel;
an active anode, disposed below the perforated anode, for replenishing metal ions;
at least one anode liquid inlet, for supplying anode liquid to the anode region;
at least one anode liquid outlet, for discharging anode liquid from the anode region;
wherein, a rectifying plate is disposed in at least one anode region, and the rectifying plate is disposed between the anode liquid inlet and the active anode in the anode region where the rectifying plate is located.

25.-27. (canceled)
